(19) United States
(12) Patent Application Publication
(10) Pub. No.: US 2017/0186919 A1
(43) Pub. Date: Jun. 29, 2017

(54) Optoelectronic Semiconductor Devices with Enhanced Light Output

(71) Applicant: Light Share, LLC, San Francisco, CA (US)

(72) Inventor: Myung Cheol Yoo, San Francisco, CA (US)

(21) Appl. No.: 15/391,690

(22) Filed: Dec. 27, 2016

Related U.S. Application Data
(60) Provisional application No. 62/272,244, filed on Dec. 29, 2015.

(51) Int. Cl. H01L 33/46; H01L 33/62; H01L 33/00; H01L 33/32

(52) U.S. Cl. CPC H01L 33/46; H01L 33/325; H01L 33/62; H01L 33/0075; H01L 33/0066; H01L 2933/0025; H01L 2933/0066

(57) ABSTRACT

Residual internal stress within optoelectronic devices such as light-emitting diodes and laser diodes is reduced to improve internal quantum efficiency and thereby increase light output.

### CROSS-REFERENCE TO RELATED APPLICATIONS

This application hereby claims priority to and incorporates by reference U.S. Provisional Patent Application No. 62/272,244 filed Dec. 29, 2015 and titled “Opto-electronic semiconductor devices with IQE-improved light output.”

### TECHNICAL FIELD

The present disclosure relates to optoelectronic semiconductor devices.

### DRAWINGS

The various embodiments disclosed herein are illustrated by way of example, and not by way of limitation, in the figures of the accompanying drawings and in which like reference numerals refer to similar elements and in which:

FIG. 1 illustrates surface area compression and tension that device and substrate layers within an optoelectronic semiconductor device impart to one another, and reduction thereof by substrate layer thinning;

FIG. 2 illustrates further reduction of compressive stress within the device layer of an optoelectronic semiconductor device through application of a material layer that imparts tensile stress to the thinned substrate;

FIG. 3 illustrates an exemplary process flow for enhancing internal quantum efficiency (IQE) and light output within semiconductor optoelectronic devices, and depicting material layer addition as a process option;

FIG. 4 illustrates an exemplary support-wafer bonding and substrate thinning according to process operations shown in FIG. 3;

FIG. 5 illustrates exemplary deposition of a reflective layer and seed metal layer according to process operations shown in FIG. 3;

FIGS. 6A and 6B illustrate exemplary approaches to application of a tensile metal layer to the seed metal layer shown in FIG. 5, including separation/singulation of the tensile metal layer during or after application;

FIG. 7 illustrates an exemplary optoelectronic device finishing and singulation operations;

FIGS. 8A, 8B and 8C illustrate exemplary top, profile and isometric views, respectively, of a processed singulated optoelectronic device; and

FIGS. 9A, 9B and 9C illustrate exemplary current vs. voltage, light-output power vs. current and IQE vs. current plots, respectively, that contrast the performance characteristics of chips with and without IQE-enhancement processing.

### DETAILED DESCRIPTION

In various embodiments herein, residual internal stress within optoelectronic devices such as light-emitting diodes (LEDs) and laser diodes (LDs) is reduced to improve internal quantum efficiency (IQE) and thereby increase light output. In a number of embodiments, for example, compressive stress on/within the quantum well of the epitaxial layer (e.g., developed by lattice mismatch and/or mismatch in thermal expansion coefficients between the thin epitaxial layer and device substrate—mismatch between GaN and sapphire, for example) is attenuated by thinning the device substrate and/or affirmatively counteracted by application of external tensile stress.

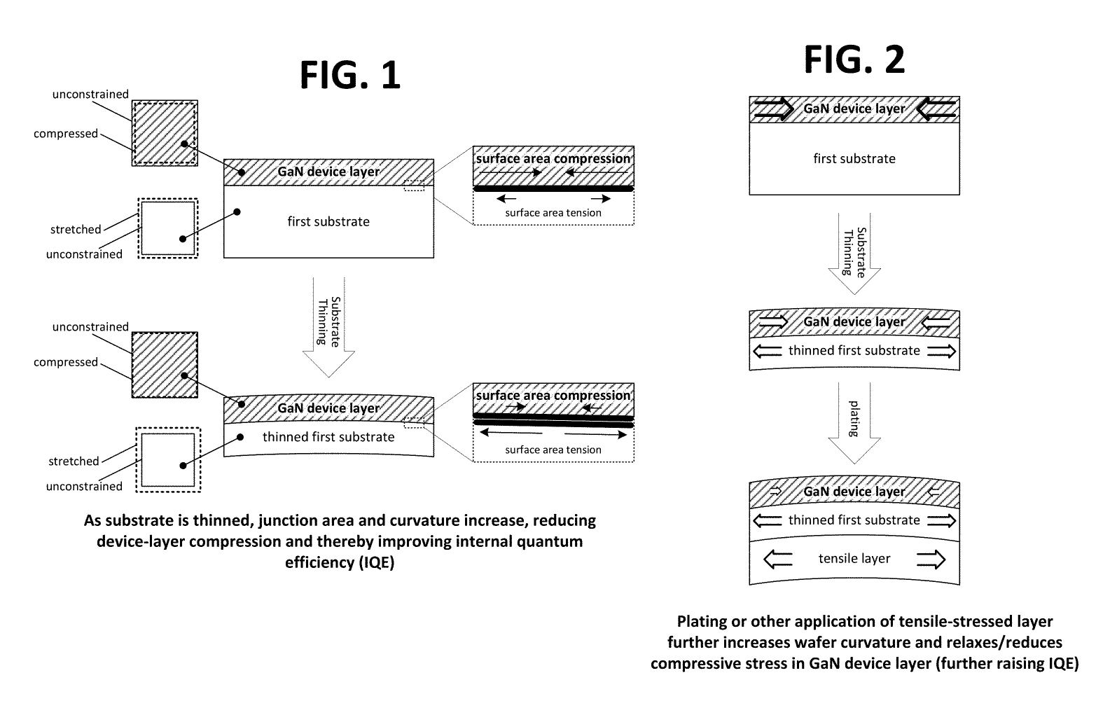

In particular embodiments, residual compressive stress within the light-emitting device layer—gallium nitride (GaN) or other semiconductor layer developed, at least in part, by epitaxial growth on an electrically insulating substrate layer, semi-conductive substrate layer or conductive substrate layer—is reduced by thinning the substrate layer itself and thus attenuating the compressive stress at its source. FIG. 1 illustrates this approach generally, showing the surface area compression and tension that the device and substrate layers impart to one another, respectively (e.g., that, if unconstrained, the device layer would expand to a larger footprint and the substrate would shrink to a smaller footprint). As the substrate layer is thinned, the surface area compression imparted by the volumetrically reduced substrate layer attenuates (compression is relieved), permitting the device layer to expand, further stretching the substrate layer. In the implementation shown, for example, thinning the substrate layer causes the multi-layer wafer to bow (device curvature increases), increasing the epitaxial junction area between the substrate and device layers, reducing the compressive stress within the device layer. In particular, reduced compressive stress within the multi-quantum well (MQW) of the device layer raises internal quantum efficiency (IQE), yielding greater light output per unit power. For example, relieving compressive stress within an indium gallium nitride or gallium nitride multi-quantum-well (i.e., InGaN/GaN MQW) active layer modifies piezoelectric fields in a manner that reduces the Quantum-confined Starks Effect (QCSE) in the MQW layer. The reduction in piezoelectric fields raises IQE, and thus improves/enhances the light output of the subject optoelectronic device.

While substrate thinning alone is sufficient to improve light output within optoelectronic devices and thus may be practiced without other significant changes to the finalized device structure, in other embodiments, one or more additional material layers are applied to the thinned substrate to impart additional tensile stress to the substrate and thereby further expand the epitaxial junction area between the substrate and device layer—further reducing compressive stress within the device layer and correspondingly increasing IQE and enhancing light output. FIG. 2 illustrates an example of such external tensile stress approach, showing that, after thinning the substrate layer, a tensile layer (e.g., metal plating or wafer bonding as discussed below) is formed or otherwise applied to the substrate layer (at the substrate surface opposite the epitaxial device layer interface) to impart tensile stress that further stretches the substrate layer, further increasing curvature of the multi-layer (composite) wafer and thus further relaxing/reducing compressive stress in the device layer to enhance IQE and light output. In a number of embodiments, for example, a 7˜8% increase in light output is achieved by substrate thinning and by metal electro-plating under tensile stress as compared with a conventional GaN/sapphire lateral LED chip. Higher (or lesser) improvements in light output may be achieved.

At least the following technical challenges are resolved in various embodiments herein to enable cost-effective and high-yield mass production of improved light-output optoelectronic devices:

practicable and controllable reduction of compressive stress within the device layer of optoelectronic devices through substrate thinning
pre-thinning bonding of support wafer and post-thinning de-bonding of same to enable thinning of the substrate layer to otherwise impracticably fragile thicknesses (i.e., thicknesses not readily feasible without support wafer)
substrate thinning techniques that yield target substrate thicknesses, generally reduced by at least 50% relative to the pre-thinning dimension, though thinning by lesser or greater percentages (e.g., thickness reduction by any amount between 20% and 90% of the pre-thinning dimension and thus 20%, 25%, . . . , 85%, 90% reduction of the pre-thinning dimension, or, alternatively specific thickness dimensions within the percentage-reduction range)
   practical and controllable reduction of compressive stress within the device layer of optoelectronic devices through addition of one or more material layers that impart tensile stress to the substrate layer
application of tensile-stress metal plating or wafer bonding as one source of external tensile stress
controlling the target thickness of the metal plating (e.g., achieving desired thicknesses of metal plating layer at any specific point between 20 and 150 μm, and thus 25, 30, 35, 40, 45, 50, 55, . . . , 145 or 150 _{μ}m—a dimension that may also be expressed as a percentage thickness relative to the thinned substrate thickness such as, for example, 20%, 25%, 30%, . . . , 390%, 395%, 400% of the substrate thickness).
ensuring adhesion between metal plating layer (a second substrate) and the epitaxial (first) substrate
   practicable technique for separating/singulating individual optoelectronic devices within the finalized multi-layer wafer to yield plural semiconductor dies
patterned electroplating of the tensile-stress metal layer
street-line etching of electroplating layer

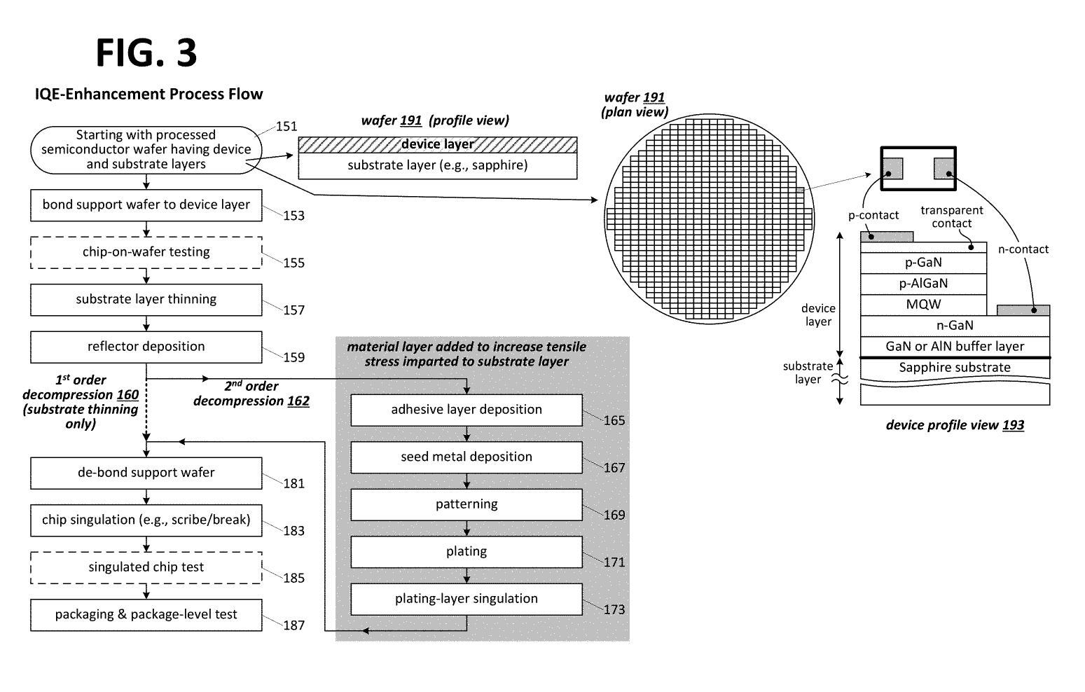

FIG. 3 illustrates an exemplary process flow for enhancing IQE (and light output) within optoelectronic semiconductor devices and depicting material layer addition as a process option (i.e., IQE enhanced either by substrate thinning or a combination of substrate thinning and tensile-stress layer application). In the embodiment shown, the IQE-enhancement process starts at 151 with a processed semiconductor optoelectronic semiconductor wafer and more specifically, a complete or substantially complete gallium nitride (GaN) light-emitting device layer over a sapphire substrate. Referring to device profile view 193 (showing an exemplary material stack of a given optoelectronic device—a GaN-based light-emitting diode (LED) in this case—among the many hundreds, thousands or more such devices to be singulated from wafer 191), the device layer itself includes multiple material layers, including a gallium nitride or aluminum nitride buffer layer and an n-doped gallium nitride layer which collectively underlie an AlInGaN-based multi-quantum well (MQW). P-doped aluminum gallium nitride and gallium nitride layers are disposed over the multi-quantum well to provide electrical conductivity between the MQW and a p-contact, while a counterpart n-contact is electrically coupled to the MQW via the n-doped gallium nitride layer. A transparent contact provides efficient current spreading for the p-GaN layer. Note that the particular device structure depicted is but one example and may be varied in numerous aspects (materials, layers, organization, etc.). Thus, the illustrated device layer should be understood to be merely an example to which the IQE enhancement process may be applied. Same or similar enhancement processes may be applied with respect to any optoelectronic device for which light output may be enhanced through reduction of compressive stress within the multi-quantum well and/or other active layers of the device.

Other substrate materials may also be used in alternative embodiments (e.g., silicon, silicon carbide, gallium arsenide (GaAs), indium phosphide (InP), etc.) and optoelectronic devices implemented with other types of semiconductors (e.g., silicon, germanium, etc.) and/or having one or more semiconductor layers doped or supplemented with additional materials (manganese, indium, aluminum, etc.) may be used in alternative embodiments. Also, the individual devices on wafer may be partially separated (e.g., scribed or etched lines that subdivide devices within the active layer and penetrate to relatively shallow scribe depths in the substrate layer) or entirely unseparated.
Temporary Support Wafer Bonding

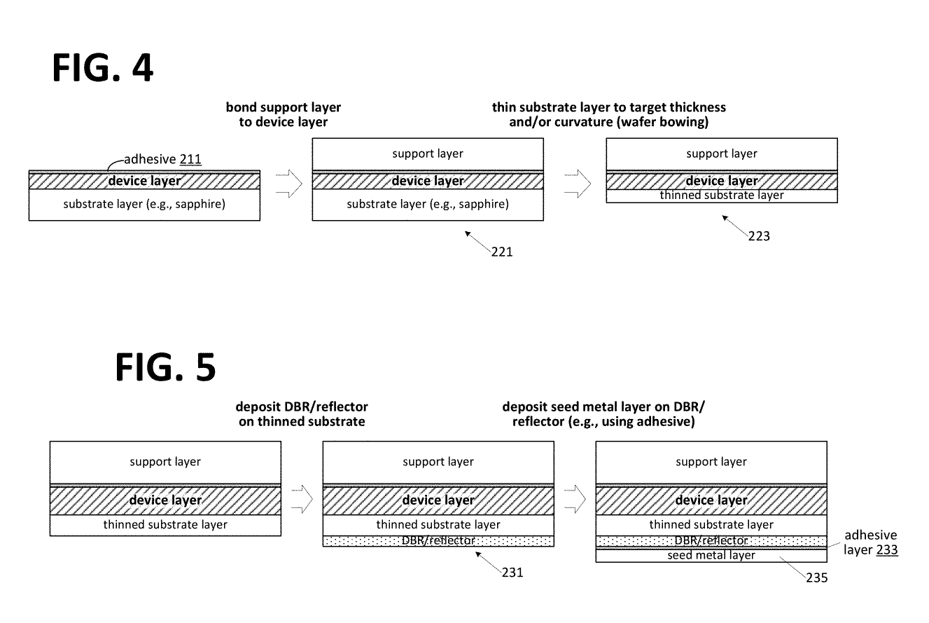

Still referring to FIG. 3, to enable the substrate layer to be thinned to a relatively fragile target thickness, a support wafer is bonded to the device layer at 153. In one approach, shown in FIG. 4 for example, an adhesive material 211 is deposited over the device layer (filling non-uniform depths of the device layer surface) followed by application (heating and pressing) of the support wafer to the adhesive film to yield the structure shown at 221—that is, sandwiching the device layer (processed semiconductor device) between the support wafer and substrate. Moreover, in a number of embodiments, transparent support-bonding adhesives are used to facilitate patterning (i.e., enabling view of isolated devices for purposes of aligning patterning beneath the thinned substrate layer) and/or the adhesive materials may be chosen for easy removal (e.g., by solvents and heat) to facilitate eventual de-bonding of the support wafer as discussed below. More generally, any practicable approach to temporarily bonding the support wafer to the device layer may be employed, including bonding without deposition of an adhesive material.
Wafer Thinning

After bonding the support wafer to the device layer, the relatively hard substrate layer is thinned as shown at 155 of FIG. 3 to yield the structure shown generally at 223 of FIG. 5, a material removal process that both reduces compressive stress within the device layer (after support layer de-bonding) and facilitates eventual chip separation (singulation). In a number of embodiments, the substrate is thinned by grinding, lapping and/or chemical-mechanical processing (CMP—planarization, polishing, etc.), including, for example and without limitation, mechanical grinding and/or lapping with a diamond embedded grinding wheel and diamond slurry. Any practicable alternative or supplemental material/mass removal operations may be practiced in alternative embodiments (e.g., dry etching of the substrate layer, stealth laser scribing, mechanical scribing by diamond stylus, sawing, etc.).

In a number of process implementations, the substrate layer is thinned to a target thickness analytically and/or empirically determined to yield a desired tensile stress within the sapphire layer (and/or relaxed compressive stress within the device layer and/or desired curvature in the final singulated device). In one embodiment, for example, a two-inch diameter sapphire wafer is thinned down from 430 μm to a target thickness ranging between 215 μm and any practicable minimum (e.g., target thickness dimension=215 μm, 210 μm, . . . , 120 μm, 115 . . . , 65 μm, 60 μm, 55 μm, . . . , 45 μm, 40 μm, 35 μm, 30 μm etc.). In general, thinning is carried out to reduce the substrate wafer thickness (which may initially be larger or smaller than 430 μm in alternative embodiments) by at least 30% and more specifically by at least 50%, or even 60%, 75%, 80% or 90%.
DBR reflector, adhesive layer, and seed metal layer fabrication

In embodiments that employ a transparent first substrate (e.g., Al₂O₃), reflectors may be deposited on the backside of the thinned first substrate as shown generally at 159 in FIG. 3 to increase light out-put of the semiconductor devices by reflecting downward-emitted photons. In the specific example shown in FIG. 5, a multi-layer distributed Bragg reflector (DBR) is deposited (e.g., by ion beam assisted deposition) on the first substrate to achieve the structure shown at 231, though metal reflectors (e.g., Al or Ag) or any other useful reflecting material or compound may be used in alternative embodiments. In one implementation, for instance, twelve (12) pairs of TiO₂/SiO₂ DBR layers are deposited on the back side of the thinned substrate layer (the thinned substrate being transparent), though more or fewer DBR layers may be fabricated in alternative embodiments.

Either of at least two branches of the FIG. 3 IQE-enhancement process flow may be implemented following reflector deposition at 159, including a first-order decompression process 160 in which compressive stress on the device layer is relieved through substrate thinning (157) alone and a second-order decompression process 162 in which additional device layer decompression is effected through addition of one or more tensile-stress material layers. In the particular process flow shown, the same final actions are carried out in both first and second-order processes and include de-bonding the support wafer at 181, singulating chips at 183 optional pre-packaging singulated chip test at 185 and then chip packaging and package-level testing at 187. In the second-order decompression path, additional operations are carried out with respect to the underside of the material stack (i.e., beneath the reflector layer) prior to proceeding with operations 181-187, including adhesive layer deposition at 165, followed by seed metal deposition at 167, patterning and plating (169 and 171) and finally plating-layer singulation 173—all these actions (and variants thereof) are described in greater detail below in connection with FIGS. 5, 6A, 6B, 7A and 7B.

Assuming that second-order decompression process 162 (one instance of the IQE-enhancement process) is to be implemented, after reflector deposition (or other manner of reflector disposition on the thinned substrate opposite the device layer), an adhesive layer 233 is deposited on the reflector layer as shown in FIG. 5 to adhere a subsequently deposited seed metal layer 235 to the underside of the reflector layer. Various thin-film deposition techniques may be employed to deposit the adhesive and/or seed metal layer including, without limitation, electron-beam evaporation, sputtering, etc., and the adhesive layer may be implemented by various compounds chosen, for example, for adhesive properties with respect to the specifically chosen seed metal layer (e.g., Ti/Au or Ti/Cu, Cr/Au, Cr/Cu, etc., for gold or copper seed metal layers or alloys of either/both of those metals).

Seed metals are generally chosen to ensure good chemical affinity and good adhesion with subsequent metal plating or bonding. In a number of embodiments, for example, copper or gold (Cu or Au) seed metal layers having a thickness in the range of 0.5—1.0 μm are formed, though layer thicknesses outside that range may be implemented in alternative embodiments. In general, in-situ deposition of DBR/reflector (i.e., no interruption of vacuum deposition process) improves adhesion between the DBR reflective layer(s) and subsequently deposited seed metal layer.
Patterning and Metal-Layer Plating/Bonding

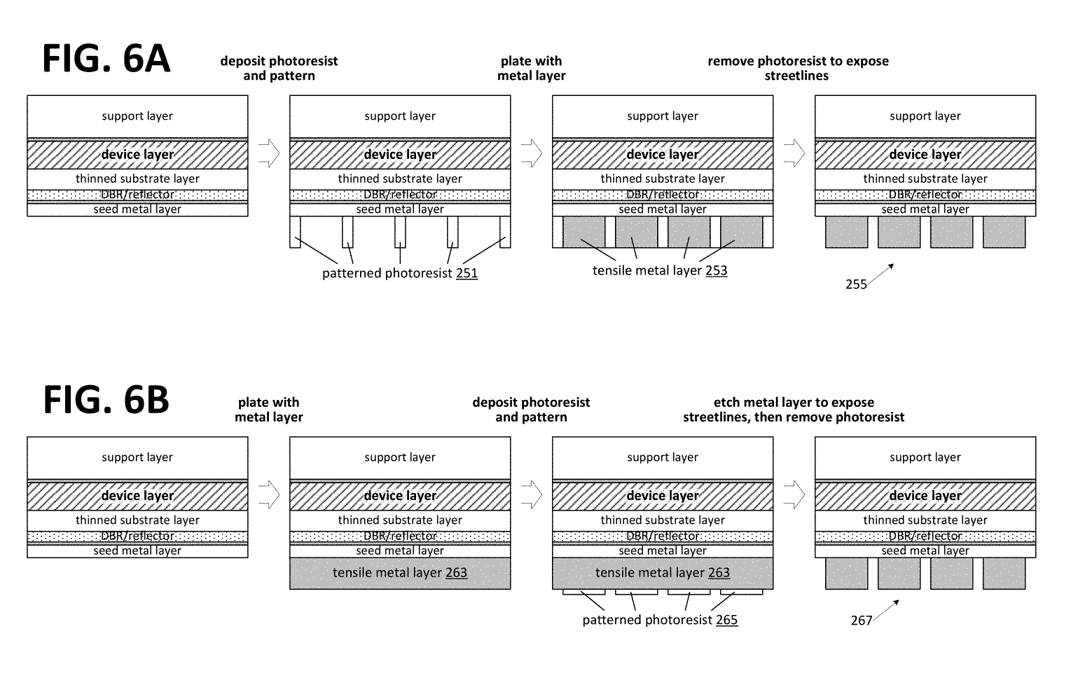

To facilitate chip separation (singulation) after disposition of a metal layer on the seed layer (e.g., through plating or bonding as discussed below), photo-resist 251 may be patterned on the seed layer prior to disposition of metal layer 253 as shown in FIG. 6A. In a number of embodiments, a relatively thick, high-tensile-stress metal layer 253 (and thus a “tensile metal layer”—which may be deemed a second substrate layer) is enabled by a relatively thick photo-resist (PR) patterning (e.g., 80 μm-thick or thicker, though thinner PR patterning may be used). In other embodiments (e.g., where wet chemical chip separation is employed), at least one of which is shown in FIG. 6B, a continuous tensile metal layer 263 is formed on the seed metal layer and patterned/separated in later singulation operations. Numerous metals and/or metal alloys may be used to implement metal layer 263 (e.g., copper (Cu), gold (Au), nickel (Ni), aluminum (al), chromium (Cr) and/or an alloy containing any one or more of copper, gold, nickel, aluminum and/or chromium), including metals or metal alloys that impart compressive rather than tensile stress to the material stack or any layer thereof. Specific examples of metal alloys that may be used to implement a metal-plating layer 263 in whole or part include, without limitation, copper-molybdenum (Cu—Mo), copper-tungsten (Cu—W) and nickel-cobalt (Ni—Co). In case of metal layer formation through wafer bonding, the metal layer may include, for example and without limitation, tungsten, molybdenum, titanium, tantalum or an alloy containing at least one of tungsten, molybdenum, titanium, tantalum.

In both embodiments FIGS. 6A and 6B, the metal layer 253/263 is disposed over the seed metal layer through electro-plating—an economical and high-throughput technique that facilitates metal layer formation in mass production—using a recipe that includes one or more high modulus metal layers and yields high tensile stress in the metal plating. Challenges arise in this approach as higher tensile stress in the metal layer generally leads to weaker adhesion between metal layer 253/263 and the seed metal layer. In a number of process implementations, this challenge is overcome (ensuring adhesion between the seed layer and metal layer despite high tensile stress developed in the metal layer) by using a graded metal-plating recipe to control the plating stress. In general, plating thicknesses are implemented within the range of 50 μm to 200 μm (e.g., 50 μm, 55 μm, 60 μm, . . . , 190 μm, 195 μm, 200 μm), though smaller or larger thickness dimensions may be implemented, particularly when different plating recipes are employed. Details of an exemplary metal-plating recipe are shown for example and without limitation in Table 1 below. As shown, for instance, after plating a 50 μm-thick Cu layer, chip curvature was changed from 1.7 k, m⁻¹ (without plating) to 2.4 k, m⁻¹, and tensile stress was changed from 0.27 GPa to 0.38 GPa, respectively.

TABLE 1
Examples of plating conditions and resulting tensile stress/curvature

| | | | Total | | |
|---|---|---|---|---|---|
| | | | thickness: | | |
| First | | | second | | |
| substrate | | Plating | substrate + | Tensile | |
| thickness | Plated | thickness | plated | stress | Curvature |
| (μm) | layer | (μm) | layer (μm) | (GPa) | (k, m⁻¹) |
| 120 | No plating | 0 | 120 | 0.27 | 1.7 |
| 120 | Cu | 50 | 170 | 0.38 | 2.4 |

Table 2 below depicts examples of plating stresses achieved with respective plating solutions, demonstrating that the plating stress can be tensile or compressive depending on the chosen recipe/solution.

TABLE 2
Plating stress for different plating solutions/recipes

| | kgf/mm² | | MPa | | GPa | |
|---|---|---|---|---|---|---|
| | min | max | min | max | min | max |
| Soft Cu | 0.5 | 1.5 | 4.903 | 14.709 | 0.005 | 0.015 |
| Hard Cu | −1 | 0.5 | −9.806 | 4.903 | −0.010 | 0.005 |
| Sulfamine Ni | −2 | −3 | −19.612 | −29.418 | −0.020 | −0.029 |
| Ni chloride | 4 | 5 | 39.224 | 49.030 | 0.039 | 0.049 |
| Cr | 4 | 7 | 39.224 | 68.642 | 0.039 | 0.069 |
| NiCo | −0.5 | 0.1 | −4.903 | 0.981 | −0.005 | 0.001 |

In other embodiments, the metal layer shown at 263 of FIG. 6B is disposed over the seed metal layer through wafer bonding. For example, a tensile metal layer having a desired thickness may be bonded to the seed metal layer (e.g., through application of heat and/or pressure). Thus, after metal-substrate wafer bonding to the seed metal layer a structure having a continuous tensile metal layer may be achieved in a manner analogous to the metal layers 263 achieved through plating as shown in FIG. 6B.
Chip Separation (Singulation)

Although plating is efficient way to fabricate a relatively thick metal layer (i.e., a second substrate, counting the thinned substrate as the first) with high tensile stress, additional challenges arise in separating chips from one another in view of the metal layer. In general, a relatively thick and ductile metal layer is difficult to separate by conventional methods, such as laser scribing or sawing, and often requires full scribing. On the other hand, hard substrate materials such as the first thinned substrate can be readily separated by scribing and breaking. In view of this insight, a number of different chip separation (die singulation) techniques are employed following application of the high-tensile-stress metal layer including, for example and without limitation, (i) removing photo-resist (PR) after patterned plating to expose street lines to hard substrate materials, and (ii) wet etch of the metal layer by chemical etchants again exposing street lines to hard substrate materials. According to the first approach (plating over patterned PR and then removing the patterned PR), shown generally at 255 in FIG. 6A, chips are separated simply by stripping the patterned photoresist after metal plating and then scribing and breaking along the exposed street lines (i.e., formed by the PR pattern). According to the second approach (etching non-patterned metal layer), shown generally in FIG. 6B, a photoresist layer is deposited over metal layer 263 and then patterned (yielding patterned photoresist 265) to expose chip separation lines. Thereafter metal layer 263 is etched (e.g., wet etched by spraying or otherwise applying chemical etchant along the streetlines) to make ready for eventual die separation, yielding the configuration shown at 267.
Support-Layer De-Bonding

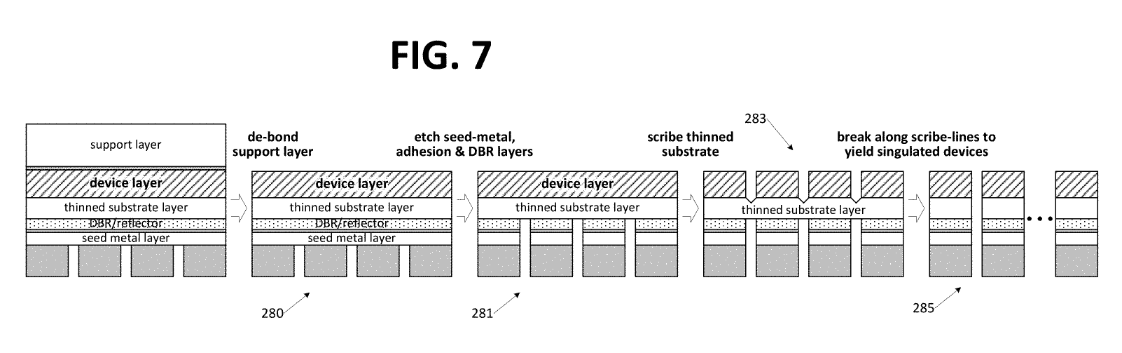

After metal layer separation as shown in FIG. 6A or FIG. 6B (i.e., preparing the way for eventual chip separation), the processed wafer is de-bonded from the support wafer as shown in FIG. 7. In a number of embodiments, adhesive materials for temporary de-bonding are readily removed by low temperature heating (<100 C) and/or application of solvents. De-bonded wafers may be further cleaned with solvent and alcohol.

Referring to FIG. 7, after support-wafer de-bonding to yield the structure shown at 280, the seed-metal, adhesive and DBR layers are etched along streetlines to render the structure shown at 281, followed by device layer etching (if not pre-etched) and substrate scribing as shown at 283, and then separating/breaking the layered structure into individual semiconductor devices as shown at 285.

Following the de-bonding/singulation process shown in FIG. 7, the exemplary final chip structure is subject to external tensile stress from the metal layer substrate formed on the back of the semiconductor devices over the thinned first substrate (i.e., with reflective layer and seed layer disposed between the first and second substrates).
Experimental Example and Results

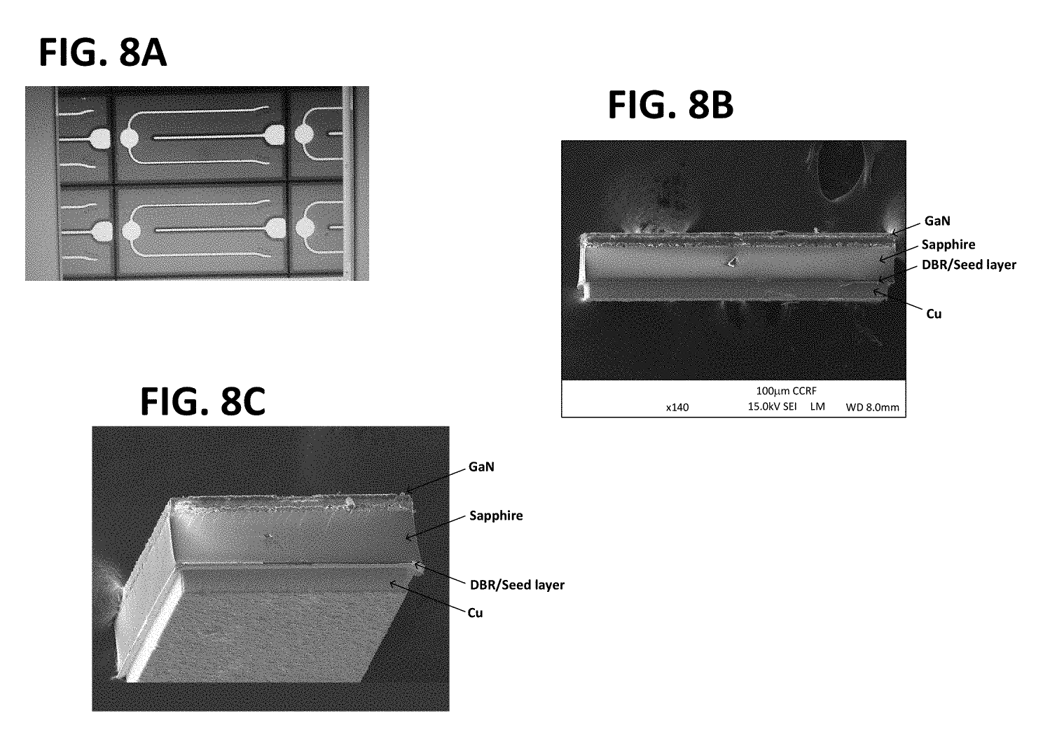

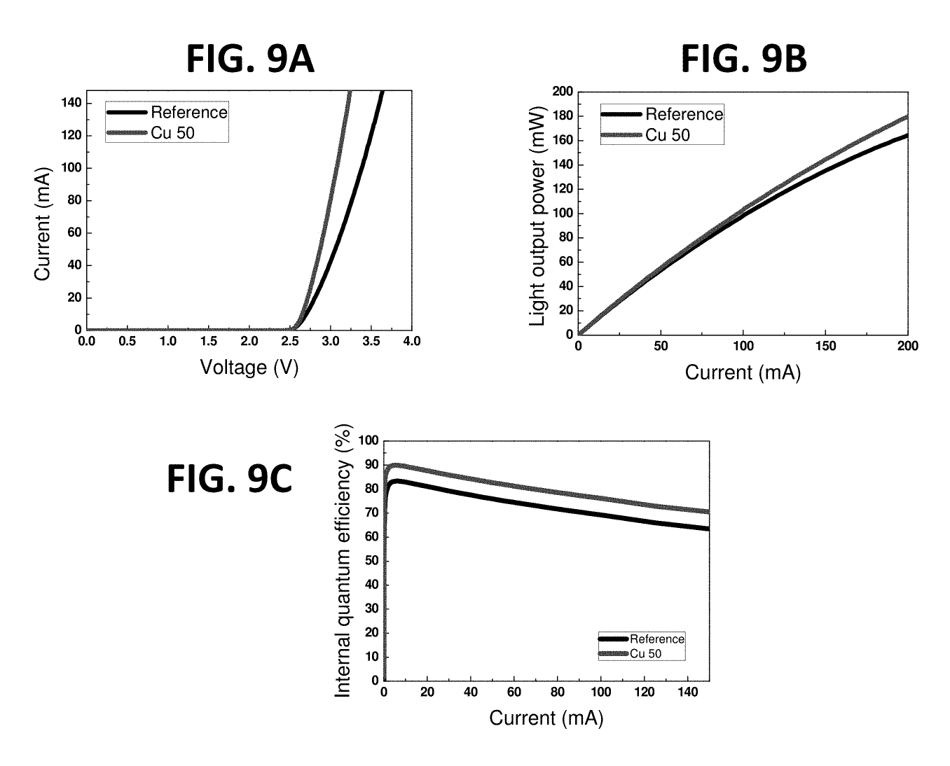

FIGS. 8A, 8B and 8C illustrate exemplary top, profile and isometric views (photographs), respectively, of a processed singulated optoelectronic device (i.e., finished, but unpackaged chip having a structure as shown at 285 and 295 in FIGS. 7A and 7B). FIGS. 9A, 9B and 9C illustrate exemplary current vs. voltage, light-output power vs. current and percentage-IQE vs. current plots, respectively, that contrast the performance characteristics of chips with (“Cu 50”) and without (“Reference”) the above-discussed IQE-enhancement processing. As shown, in a number of embodiments, light output was increased by approximately 7% to 8% after processing lateral chips with external tensile stress.

In the foregoing description and in the accompanying drawings, specific terminology and drawing symbols have been set forth to provide a thorough understanding of the disclosed embodiments. In some instances, the terminology and symbols may imply specific details that are not required to practice those embodiments. For example, any of the specific dimensions, quantities, material types, fabrication steps and the like can be different from those described above in alternative embodiments. The term “coupled” is used herein to express a direct connection as well as a connection through one or more intervening circuits or structures. The terms “exemplary” and “embodiment” are used to express an example, not a preference or requirement. Also, the terms “may” and “can” are used interchangeably to denote optional (permissible) subject matter. The absence of either term should not be construed as meaning that a given feature or technique is required.

Various modifications and changes can be made to the embodiments presented herein without departing from the broader spirit and scope of the disclosure. For example, features or aspects of any of the embodiments can be applied in combination with any other of the embodiments or in place of counterpart features or aspects thereof. Accordingly, the specification and drawings are to be regarded in an illustrative rather than a restrictive sense.

What is claimed is:

1. An optoelectronic semiconductor device comprising:
an insulating substrate layer having a thickness less than 300 μm; and
a light-emitting device layer disposed on the insulating substrate layer.

2. The optoelectronic semiconductor device of claim 1 further comprising a tensile metal layer disposed beneath the insulating substrate layer such that the insulating substrate layer is disposed between the tensile metal layer and the light-emitting device layer to impart tensile stress to the insulating substrate layer.

3. The optoelectronic semiconductor device of claim 2 further comprising a reflective layer sandwiched between the insulating substrate and the tensile metal layer, the reflective layer to reflect photons emitted from the light-emitting device layer.

4. The optoelectronic semiconductor device of claim 3 further comprising a seed metal layer disposed between the metal layer and the reflective layer.

5. The optoelectronic semiconductor device of claim 2 wherein the tensile metal layer comprises a plated metal layer.

6. The optoelectronic semiconductor device of claim 2 wherein the tensile metal layer comprises wafer bonded metal layer.

7. The optoelectronic semiconductor device of claim 2 wherein the tensile metal layer is at least 30 μm thick.

8. The optoelectronic semiconductor device of claim 2 wherein the tensile metal layer comprises at least one of copper, gold, aluminum, nickel, chromium or an alloy containing at least one of copper, gold, aluminum, nickel or chromium.

9. The optoelectronic semiconductor device of claim 2 wherein the bonded tensile metal layer comprises at least one of tungsten, molybdenum, titanium, tantalum or an alloy containing at least one of tungsten, molybdenum, titanium, tantalum.

10. The optoelectronic semiconductor device of claim 2 wherein the insulating substrate layer comprises an aluminum oxide layer and wherein the light-emitting device layer comprises layers of gallium nitride respectively doped to form a p-n junction.

11. The optoelectronic semiconductor device of claim 8 wherein the aluminum oxide layer comprises a sapphire layer.

12. The optoelectronic semiconductor device of claim 1 wherein the insulating substrate layer comprises a sapphire layer and wherein the light-emitting device layer comprises layers of gallium nitride respectively doped to form a p-n junction.

13. A method of fabricating one or more optoelectronic semiconductor devices each having a light-emitting device layer disposed on an insulating substrate layer, the method comprising:
thinning the insulating substrate layer to a thickness dimension less than 300 μm; and
forming a reflective layer on the insulating substrate layer such that the insulating substrate layer is sandwiched between the light-emitting device layer and the reflective layer.

14. The method of claim 13 wherein thinning the insulating substrate layer to a thickness dimension less than 300 μm comprises thinning the insulating substrate layer by at least half its initial thickness dimension.

15. The method of claim 13 further comprising disposing a tensile metal layer on the reflective layer such that the reflective layer is disposed between the tensile metal layer and the insulating substrate.

16. The method of claim 15 wherein disposing the tensile metal layer on the reflective layer comprises disposing a seed metal layer on the reflective layer and then forming, as the tensile metal layer, a metal plating over the seed metal layer.

17. The method of claim 16 wherein the metal plating comprises at least one of copper, gold, aluminum, nickel, chromium or an alloy containing at least one of copper, gold, aluminum, nickel or chromium.

18. The method of claim 16 wherein forming the metal plating over the seed metal layer comprises:
patterning photoresist over the seed metal layer;
forming the metal plating within the patterned photoresist; and
removing the patterned photoresist to reveal, within the metal plating, streetlines to facilitate singulation of the optoelectronic devices.

19. The method of claim 16 further comprising:
patterning photoresist over the metal plating; and
etching streetlines within regions of the metal plating not covered by the patterned photoresist.

20. The method of claim 13 further comprising bonding a support layer to the light-emitting device layer prior to thinning the insulating substrate layer, and then de-bonding the support layer from the light-emitting device layer after thinning the insulating substrate layer.

21. The method of claim 13 wherein thinning the insulating substrate layer to a thickness less than 300 μm comprises thinning a sapphire substrate layer by at least half its initial dimension.

22. The method of claim 13 wherein thinning the insulating substrate layer to a thickness dimension less than 300 μm comprises at least one of mechanically grinding the insulating substrate layer, lapping the insulating substrate layer or chemical-mechanical processing of the insulating substrate layer to remove material therefrom.

23. An optoelectronic semiconductor device comprising:
a semiconductor substrate layer having a thickness less than 300 μm; and
a light-emitting device layer disposed on the semiconductor substrate layer.
